(19) United States
(12) Patent Application Publication
(10) Pub. No.: US 2024/0312938 A1
(43) Pub. Date: Sep. 19, 2024

(54) SEMICONDUCTOR DEVICE

(71) Applicant: SAMSUNG ELECTRONICS CO., LTD., Suwon-si (KR)

(72) Inventors: Junhyoung Kim, Seoul (KR); Taemok Gwon, Seoul (KR); Seungmin Lee, Seoul (KR)

(21) Appl. No.: 18/674,610

(22) Filed: May 24, 2024

Related U.S. Application Data
(63) Continuation of application No. 17/172,276, filed on Feb. 10, 2021.

(30) Foreign Application Priority Data
Jun. 16, 2020 (KR) 10-2020-0073052

(51) Int. Cl. H01L 23/00; H01L 23/522; H01L 25/00; H01L 25/065; H01L 25/18; H10B 41/27; H10B 43/27

(52) U.S. Cl. CPC H01L 24/08; H01L 23/5226; H01L 24/80; H01L 25/0657; H01L 25/18; H01L 25/50; H10B 41/27; H10B 43/27; H01L 2224/08145; H01L 2224/80895; H01L 2224/80896; H01L 2924/1431; H01L 2924/14511

(57) ABSTRACT

A semiconductor device includes first gate electrodes, a first channel structure penetrating the first gate electrodes and including a first channel layer and a first channel filling insulating layer, second gate electrodes above the first gate electrodes, a second channel structure penetrating the second gate electrodes and including a second channel layer and a second channel filling insulating layer, and a central wiring layer between the first gate electrodes and the second gate electrodes and connected to the first channel layer and the second channel layer, wherein the first channel layer and the second channel layer are connected to each other in a region surrounded by the central wiring layer, and the first channel filling insulating layer and the second channel filling insulating layer are connected to each other in a region surrounded by the central wiring layer.

### CROSS-REFERENCE TO RELATED APPLICATION

This application is a continuation of U.S. application Ser. No. 17/172,276, filed Feb. 10, 2021, which claims priority to Korean Patent Application No. 10-2020-0073052, filed on Jun. 16, 2020, in the Korean Intellectual Property Office, and is entitled “Semiconductor Device,” all of which are incorporated by reference herein in their entireties.

### BACKGROUND

### 1. Field

Example embodiments relate to a semiconductor device.

### 2. Description of the Related Art

To provide a reduced volume and to process high capacity data, a semiconductor device may be formed to have an increased integration density. As one approach for improving integration density of a semiconductor device, a semiconductor device in which semiconductor structures are bonded to each other using a wafer bonding method has been considered.

### SUMMARY

Embodiments are directed to a semiconductor device, including: a first semiconductor structure including a substrate and a circuit device disposed on the substrate; and a second semiconductor structure connected to the first semiconductor structure and on the first semiconductor structure. The second semiconductor structure may include: a first memory cell structure including first gate electrodes stacked in a first direction perpendicular to an upper surface of the substrate and spaced apart from each other, a first channel structure penetrating the first gate electrodes, and a first bit line disposed below the first channel structure; a second memory cell structure disposed above the first memory cell structure, and including second gate electrodes stacked in the first direction perpendicular to the upper surface of the substrate and spaced apart from each other, a second channel structure penetrating the second gate electrodes, and a second bit line disposed above the second channel structure; and a source conductive layer disposed between the first memory cell structure and the second memory cell structure. The first channel structure and the second channel structure may include a channel layer connected between the first channel structure and the second channel structure. The source conductive layer may surround the channel layer and may be in contact with the channel layer.

Embodiments are also directed to a semiconductor device, including: first gate electrodes stacked in a first direction and spaced apart from each other; a first channel structure penetrating the first gate electrodes and including a first channel layer and a first channel filling insulating layer; second gate electrodes stacked in the first direction and spaced apart from each other above the first gate electrodes; a second channel structure penetrating the second gate electrodes and including a second channel layer and a second channel filling insulating layer; and a central wiring layer disposed between the first gate electrodes and the second gate electrodes and connected to the first channel layer and the second channel layer. The first channel layer and the second channel layer may be connected to each other in a region surrounded by the central wiring layer, and the first channel filling insulating layer and the second channel filling insulating layer may be connected to each other in the region surrounded by the central wiring layer.

Embodiments are also directed to a semiconductor device, including: a first semiconductor structure including a substrate and a circuit device disposed on the substrate; and a second semiconductor structure bonded to the first semiconductor structure on the first semiconductor structure. The second semiconductor structure may include: a first memory cell structure including first gate electrodes stacked in a first direction perpendicular to an upper surface of the substrate and spaced apart from each other, a first channel structure penetrating the first gate electrodes, and a first wiring layer disposed below the first channel structure; a second memory cell structure disposed above the first memory cell structure, and including second gate electrodes stacked in the first direction and spaced apart from each other, a second channel structure penetrating the second gate electrodes, and a second wiring layer disposed above the second channel structure; and a central wiring layer disposed between the first memory cell structure and the second memory cell structure and connected to the first channel structure and the second channel structure. First regions of the first channel structure and the second channel structure may extend continuously between the first channel structure and the second channel structure.

### BRIEF DESCRIPTION OF DRAWINGS

Features will become apparent to those of skill in the art by describing in detail example embodiments with reference to the attached drawings in which:

FIG. 1 is a schematic block view showing a semiconductor device according to an example embodiment;

FIG. 2 is a schematic layout view showing an arrangement of a semiconductor device according to an example embodiment;

FIGS. 3A and 3B are equivalent circuit views showing a memory cell array of a semiconductor device according to an example embodiment;

FIG. 4 is a schematic cross-sectional view showing a semiconductor device according to an example embodiment;

FIG. 5 is a schematic enlarged view showing a portion of a semiconductor device according to an example embodiment;

FIGS. 6A and 6B are schematic enlarged cross-sectional views showing a portion of a semiconductor device according to example embodiments;

FIG. 7 is a schematic enlarged cross-sectional view showing a semiconductor device according to an example embodiment;

FIG. 8 is a schematic cross-sectional view showing a semiconductor device according to an example embodiment;

FIGS. 9A and 9B are schematic cross-sectional views showing a semiconductor device according to example embodiments;

FIGS. 10A and 10B are schematic perspective views showing a semiconductor device according to an example embodiment; and

FIGS. 11A to 11M are schematic cross-sectional views showing a method of manufacturing a semiconductor device according to an example embodiment.

### DETAILED DESCRIPTION

In the description below, the terms such as “upper,” “upper portion,” “upper surface,” “upper end,” “lower,” “lower portion,” “lower surface,” “lower end,” and “side surface” are used with reference to the drawings.

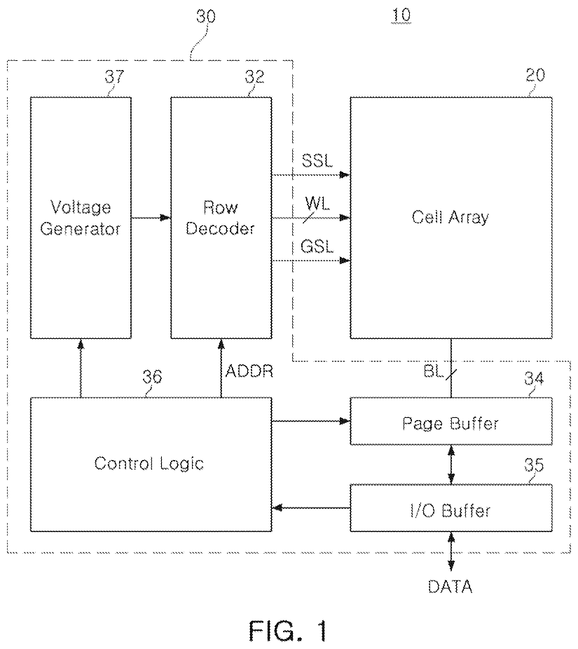

FIG. 1 is a schematic block view showing a semiconductor device according to an example embodiment.

Referring to FIG. 1, a semiconductor device 10 may include a memory cell array 20 and a peripheral circuit 30. The peripheral circuit 30 may include a row decoder 32, a page buffer 34, an input and output buffer (input/output buffer) 35, a control logic 36, and a voltage generator 37.

The memory cell array 20 may include a plurality of memory blocks, and each of the memory blocks may include a plurality of memory cells. The plurality of memory cells may be connected to the row decoder 32 through a string select line SSL, word lines WL, and a ground select line GSL, and may be connected to the page buffer 34 through bit lines BL. In an example embodiment, memory cells arranged in a same row may be connected to a same word line WL, and memory cells arranged in a same column may be connected to a same bit line BL.

The row decoder 32 may, by decoding an input address ADDR, generate and transfer driving signals of the word line WL. The row decoder 32 may provide a word line voltage, generated from the voltage generator 37, to each of a selected word line WL and non-selected word lines WL in response to control of the control logic 36.

The page buffer 34 may be connected to the memory cell array 20 through the bit lines BL and may read data stored in the memory cells. The page buffer 34 may temporarily store data to be stored in the memory cell or may sense data stored in the memory cells. The page buffer 34 may include a column decoder and a sense amplifier. The column decoder may selectively activate the bit lines BL, and the sense amplifier may sense a voltage of a bit line BL selected by the column decoder and may read data stored in a selected memory cell during a read operation.

The input/output buffer 35 may receive data DATA and may transfer the data DATA to the page buffer 34 during a program operation, and during a read operation, the input/output buffer 35 may output the data DATA received from the page buffer 34 to an external entity. The input/output buffer 35 may transfer an input address or an input command to the control logic 36.

The control logic 36 may control operations of the row decoder 32 and the page buffer 34. The control logic 36 may receive a control signal and an external voltage transferred from an external entity, and may operate according to the control signal. The control logic 36 may control read, write, and/or erase operations in response to the control signals.

The voltage generator 37 may generate voltages required for an internal operation, such as a program voltage, a read voltage, an erase voltage, and the like, for example, using an external voltage. A voltage generated by the voltage generator 37 may be transferred to the memory cell array 20 through the row decoder 32.

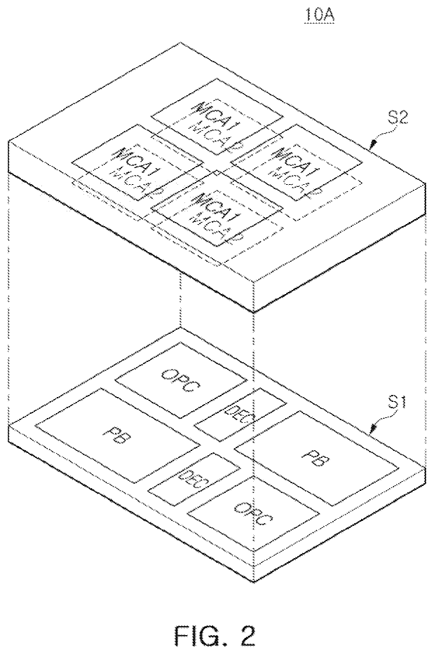

FIG. 2 is a schematic layout view showing of arrangement of a semiconductor device according to an example embodiment.

Referring to FIG. 2, a semiconductor device 10A may include first and second semiconductor structures S1 and S2 stacked in a vertical direction. In an example embodiment, the second semiconductor structure S2 may be stacked on the first semiconductor structure S1. The first semiconductor structure S1 may include the peripheral circuit 30 in FIG. 1, and the second semiconductor structure S2 may include the memory cell array 20 in FIG. 1.

The first semiconductor structure S1 may include a row decoder DEC, a page buffer PB, and one or more other peripheral circuits OPC. The row decoder DEC may correspond to the row decoder 32 described in the aforementioned example embodiment with reference to FIG. 1, and the page buffer PB may be a region corresponding to the page buffer 34. Also, the other peripheral circuit OPC may be a region including the control logic 36 and the voltage generator 37 shown in FIG. 1, and may include, for example, a latch circuit, a cache circuit, or a sense amplifier. The other peripheral circuit OPC may include the input/output buffer 35 shown in FIG. 1, and may include an electrostatic discharge (ESD) device or a data input/output circuit. In an example embodiment, the input/output buffer 35 may be disposed to form a separate region on a circumference of the other peripheral circuit OPC.

At least a portion of the various circuit regions DEC, PB, and OPC in the first semiconductor structure S1 may be disposed below memory cell arrays MCA1 and MCA2 of the second semiconductor structure S2. In an example embodiment, the page buffer PB and the other peripheral circuit OPC may be disposed to overlap, for example, in the vertical direction, the memory cell arrays MCA1 and MCA2 below the memory cell arrays MCA1 and MCA2. However, in an example embodiment, the circuits included in the first semiconductor structure S1 and arrangement forms thereof may be varied, and accordingly, the circuits overlapping the memory cell arrays MCA1 and MCA2 may also be varied. Also, in an example embodiment, the circuit regions DEC, PB, and OPC may have a shape in which the arrangement shape shown in FIG. 2 is repetitively arranged according to the numbers and sizes of the memory cell arrays MCA1 and MCA2.

The second semiconductor structure S2 may include the memory cell arrays MCA1 and MCA2. The memory cell arrays MCA1 and MCA2 may include first and second memory cell arrays MCA1 and MCA2 vertically stacked, and each of the first and second memory cell arrays MCA1 and MCA2 may be disposed on the same plane, disposed side by side, and spaced apart from each other. For example a plurality of the first memory cell arrays MCA1 may be arranged on a first plane, disposed side by side, and spaced apart from each other, and a plurality of the second memory cell arrays MCA2 may be arranged on a second plane, for example, below the first plane in the vertical direction, disposed side by side, and spaced apart from each other. In an example embodiment, the number of the memory cell arrays MCA1 and MCA2, the number of layers of the memory cell arrays MCA1 and MCA2, and the arrangement form of the memory cell arrays MCA1 and MCA2 may be varied.

In an example embodiment, pad regions for transmitting electrical signals to and receiving electrical signals from an external device may be further disposed on at least one side of the memory cell arrays MCA1 and MCA2. In the semiconductor device 10A, the pad regions may be electrically connected to an input and output circuit, for example, the data input/output circuit, corresponding to the input/output buffer 35 shown in FIG. 1 among circuits in the other peripheral circuit OPC of the first semiconductor structure S1.

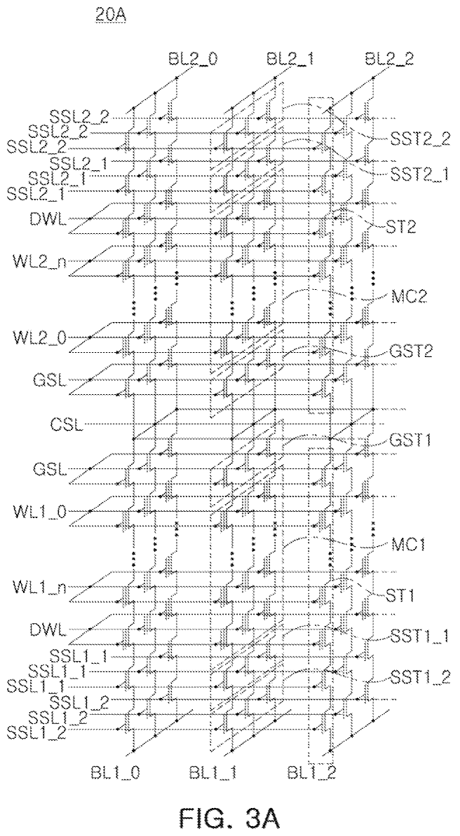

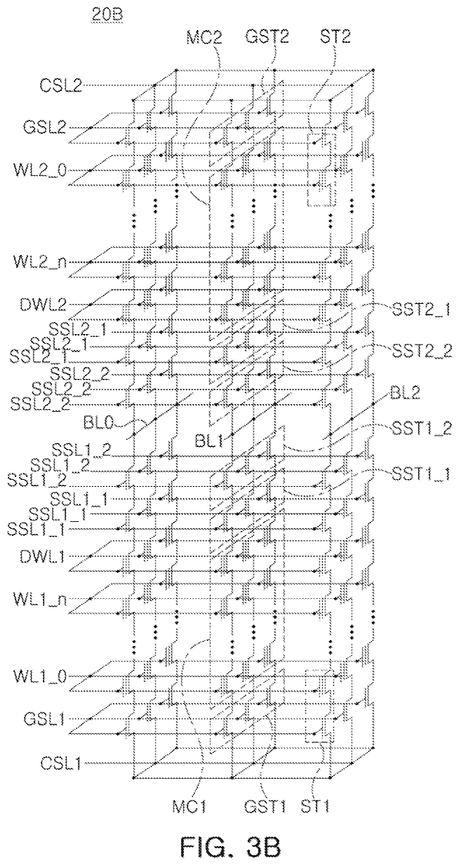

FIGS. 3A and 3B are equivalent circuit views showing a cell array of a semiconductor device according to an example embodiment.

Referring to FIG. 3A, a memory cell array 20A may include a plurality of first memory cell strings ST1, and the plurality of first memory cell strings ST1 may include first memory cells MC1 connected with each other in series, and a first ground select transistor GST1 and first string select transistors SST1_1 and SST1_2, connected to both ends of the first memory cells MC1 in series. The plurality of first memory cell strings ST1 may be connected to each of first bit lines BL1_0 to BL1_2 in parallel, respectively. The plurality of first memory cell strings ST1 may be connected to a common source line CSL in common. Accordingly, a plurality of first memory cell strings ST1 may be disposed between the plurality of first bit lines BL1_0 to BL1_2 and a single common source line CSL. In the example embodiment, a plurality of the common source lines CSL may be arranged two-dimensionally.

Also, the memory cell array 20A may include a plurality of second memory cell strings ST2 disposed above the common source line CSL. The plurality of second memory cell strings ST2 may include second memory cells MC2 connected to each other in series, and a second ground select transistor GST2 and second string select transistors SST2_1 and SST2_2, connected to both ends of second memory cells MC2 in series. The plurality of second memory cell strings ST2 may be connected to second bit lines BL2_0 to BL2_2 in parallel, respectively. The plurality of second memory cell strings ST2 may be connected to the common source line CSL in common. Accordingly, a plurality of second memory cell strings ST2 may be disposed between the plurality of second bit lines BL2_0 to BL2_2 and a single common source line CSL.

The common source line CSL disposed in a center of the memory cell array 20A may be electrically connected to the upper and lower first and second memory cell strings ST1 and ST2 in common. The first and second memory cell strings ST1 and ST2 may have a substantially symmetrical circuit structure around the common source line CSL. The first and second memory cell strings ST1 and ST2 may be independently driven by the first bit lines BL1_0 to BL1_2 and the second bit lines BL2_0 to BL2_2, respectively. In the description below, the first and second memory cell strings ST1 and ST2 will be described together.

The memory cells MC1 and MC2, connected to each other in series, may be controlled by word lines WL1_0 to WL1_n and WL2_0 to WL2_n for selecting the memory cells MC1 and MC2, respectively. Each of the memory cells MC1 and MC2 may include a data storage element. Gate electrodes of the memory cells MC1 and MC2 disposed at substantially the same distance from the common source line CSL may be connected to one of the word lines WL1_0 to WL1_n and WL2_0 to WL2_n in common and may be in an equipotential state. In another implementation, even when the gate electrodes of the memory cells MC1 and MC2 are disposed at substantially the same distance from the common source lines CSL, the gate electrodes disposed in different rows or columns may be independently controlled.

The ground select transistors GST1 and GST2 may be controlled by the ground select lines GSL1 and GSL2 and may be connected to the common source line CSL. The string select transistors SST1_1, SST1_2, SST2_1, and SST2_2 may be controlled by string select lines SSL_1, SSL1_2, SSL2_1, and SSL2_2, and may be connected to the first and second bit lines BL1_0 to BL1_2 and BL2_0 to BL2_2. FIG. 2A shows a structure in which a single ground select transistor GST1 and GST2 and two string select transistors SST1_1, SST1_2, SST2_1, and SST2_2 are connected to the plurality of memory cells MC1 and MC2, connected to each other in series, respectively, but a single string select transistor may be connected to the plurality of memory cells MC1 and MC2 or a plurality of ground select transistors may be connected to the plurality of memory cells MC1 and MC2. One or more dummy lines DWL1 and DWL2 or buffer lines may be further disposed between the uppermost word line WL1_n and WL2_n of the word lines WL1_0 to WL1_n and WL2_0 to WL2_n and the string select lines SSL_1, SSL1_2, SSL2_1, and SSL2_2. In the example embodiment, one or more dummy lines may also be disposed between the lowest word lines WL1_0 and WL2_0 and the ground select lines GSL1 and GSL2. In an example embodiment, the term “dummy” is used to refer to an element that has a structure and a shape the same as or similar to the structure and the shape of the other component but that does not have a substantial function in the device.

When a signal is applied to the string select transistors SST1_1, SST1_2, SST2_1, SST2_2 through the string select lines SSL_1, SSL1_2, SSL2_1, and SSL2_2, a signal applied through the first and second bit lines BL1_0 to BL1_2 and BL2_0 to BL2_2 may be transferred to the memory cells MC1 and MC2 connected each other in series such that data read and write operations may be performed. Also, by applying a predetermined erase voltage through the substrate, an erase operation for erasing data written in the memory cells MC1 and MC2 may be performed. In another implementation, an erase operation may be performed by an erase transistor which may be disposed on an external side of the ground select transistors GST1 and GST2 and/or an external side of the string select transistors SST1_1, SST1_2, SST2_1, and SST2_2 and may be used for an erase operation using a gate induced drainage current (GIDL) phenomenon. In an example embodiment, the memory cell array 20A may include at least one dummy memory cell string.

Referring to FIG. 3B, in a memory cell array 20B, common bit lines BL0 to BL2 may be disposed in a center, instead of the common source line CSL shown in FIG. 3A. The common bit lines BL0 to BL2 may be electrically connected to the upper and lower first and second memory cell strings ST1 and ST2 in common. The first and second memory cell strings ST1 and ST2 may have a substantially symmetrical circuit structure around the common bit lines BL0 to BL2. The first and second memory cell strings ST1 and ST2 may be connected to first and second common source lines CSL1 and CLS2, respectively.

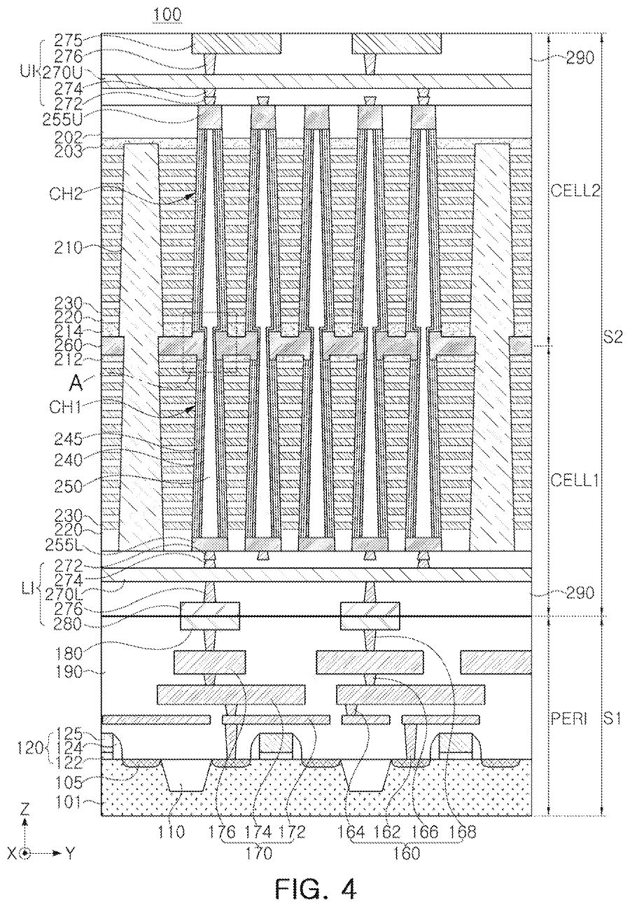

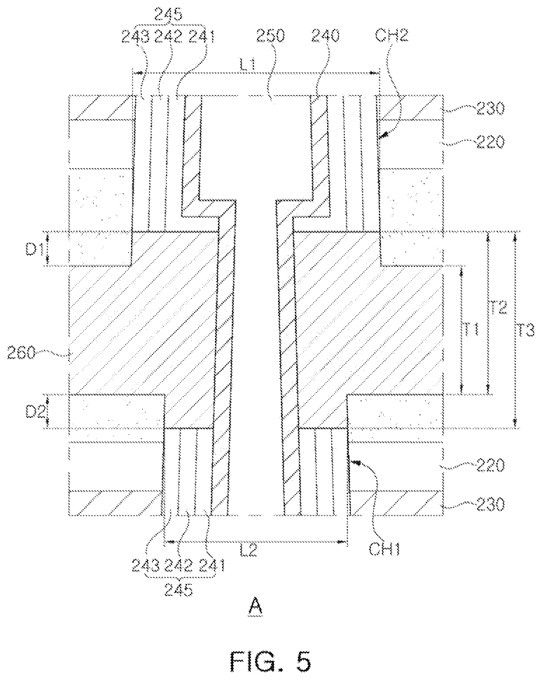

FIG. 4 is a schematic cross-sectional view showing a semiconductor device according to an example embodiment. FIG. 5 is a schematic enlarged view showing a portion of a semiconductor device according to an example embodiment. In particular, FIG. 5 shows region “A” shown in FIG. 4.

Referring to FIGS. 4 and 5, the semiconductor device 100 may include a first semiconductor structure S1 and a second semiconductor structure S2 stacked vertically. Similarly to the first semiconductor structure S1 in FIG. 2, the first semiconductor structure S1 may include a peripheral circuit region PERI. The second semiconductor structure S2 may include first and second memory cell regions CELL1 and CELL2 similarly to the second semiconductor structure S2 shown in FIG. 2.

The first semiconductor structure S1 may include a substrate 101, source/drain regions 105 and device isolation layers 110 in the substrate 101, circuit devices 120 disposed on the substrate 101, circuit contact plugs 160, circuit wiring lines 170, first bonding pads 180, and a peripheral insulating layer 190.

The substrate 101 may have an upper surface extending in the x direction and the y direction. An active region may be defined on the substrate 101 by the device isolation layers 110. The source/drain regions 105 including impurities may be disposed in a portion of the active region. The substrate 101 may include a semiconductor material, such as a group IV semiconductor, a group III-V compound semiconductor, or a group II-VI compound semiconductor. In an example embodiment, the substrate 101 may be provided as a single crystalline bulk wafer.

The circuit devices 120 may include transistors, for example, planar transistors. Each of the circuit devices 120 may include a circuit gate dielectric layer 122, a spacer layer 124, and a circuit gate electrode 125. The source/drain regions 105 may be disposed in the substrate 101 on opposite sides of the circuit gate electrode 125.

The peripheral insulating layer 190 may be disposed on the circuit device 120 on the substrate 101. The circuit contact plugs 160 may penetrate the peripheral insulating layer 190 and may be connected to the source/drain regions 105 and the circuit gate electrode 125. The circuit contact plugs may include first to fourth contact plugs 162, 164, 166, and 168 disposed in order from the substrate 101. An electrical signal may be applied to the circuit device 120 by the circuit contact plugs 160. In a region not shown in the view, the circuit contact plugs 160 may also be connected to the circuit gate electrode 125. The circuit wiring lines 170 may be connected to the circuit contact plugs 160, and may include first to third circuit wiring lines 172, 174, and 176 forming a plurality of layers.

The first bonding pads 180 may be arranged to be connected to the fourth circuit contact plugs 168 such that upper surfaces of the first bonding pads 180 may be exposed to an upper surface of the first semiconductor structure S1 through the peripheral insulating layer 190. The first bonding pads 180 may function as a bonding layer, along with second bonding pads 280 of the second semiconductor structure S2, for bonding the first semiconductor structure S1 with the second semiconductor structure S2. The first bonding pads 180 may have a total planar size larger than a total planar size of the other wiring structures to provide the bonding with the second semiconductor structure S2 and an electrical connection path according to the bonding. The first bonding pads 180 may be disposed in positions corresponding to the second bonding pads 280, and may have a size the same as or similar to the size of the second bonding pads 280. The first bonding pads 180 may include a conductive material such as copper (Cu), for example.

The second semiconductor structure S2 may include a source conductive layer 260, which may be a central wiring layer, and the first and second memory cell regions CELL1 and CELL2 stacked vertically around the source conductive layer 260.

The first memory cell region CELL1 may include gate electrodes 230 stacked in the vertical or z direction and spaced apart from each other, interlayer insulating layers 220 alternately stacked with the gate electrodes 230, first channel structures CH1 penetrating the gate electrodes 230, a lower region of the separation insulating layer 210 penetrating the gate electrodes 230, and a first wiring structure L1 disposed below the first channel structures CH1. The first memory cell region CELL1 may further include a first horizontal conductive layer 212 disposed on a lower surface of the source conductive layer 260 and a cell region insulating layer 290. Each of the first channel structures CH1 may include a gate dielectric layer 245, a channel layer 240, a channel filling insulating layer 250, and a first channel pad 255L, disposed in order from the gate electrodes 230. A first wiring structure LI may include first contact plugs 272, second contact plugs 274, first bit lines 270L, third contact plugs 276, and second bonding pads 280, disposed in the cell region insulating layer 290 and stacked in order downwardly from the first channel structures CH1.

The second memory cell region CELL2 may include the gate electrodes 230 stacked in the z direction and spaced apart from each other, interlayer insulating layers 220 alternately stacked with the gate electrodes 230, second channel structures CH2 penetrating the gate electrodes 230, an upper region of the separation insulating layer 210 penetrating the gate electrodes 230, and a second wiring structure UI disposed above the second channel structures CH2. The second memory cell region CELL2 may further include a second horizontal conductive layer 214 disposed on an upper surface of the source conductive layer 260, a support layer 203 and a substrate insulating layer 202 on an uppermost gate electrode 230, and a cell region insulating layer 290. Each of the second channel structures CH2 may include a gate dielectric layer 245, a channel layer 240, a channel filling insulating layer 250, and a second channel pad 255U, disposed in order from the gate electrodes 230. A second wiring structure UI may include first contact plugs 272, second contact plugs 274, second bit lines 270U, third contact plugs 276, and upper wiring lines 275, disposed in the cell region insulating layer 290 and stacked in order upwardly from the second channel structures CH2.

The gate electrodes 230 may be stacked in the z direction and may be spaced apart from each other in the first and second memory cell regions CELL1 and CELL2 such that the gate electrodes 230 may form a stack structure along with the interlayer insulating layers 220. The gate electrodes 230 may include electrodes forming a ground select transistor, memory cells, and a string select transistor. The number of gate electrodes 230 constituting the memory cells may be determined according to capacity of the semiconductor device 100. In an example embodiment, the gate electrodes 230 forming each of the string select transistor and the ground select transistor may be one or two or more, and may have a structure the same as or different from the structure of the gate electrodes 230 of the memory cells. Also, the gate electrodes 230 may further include a gate electrode 230 disposed above the gate electrode 230 constituting the string select transistor and forming an erase transistor used for an erase operation using the GIDL phenomenon. A portion of the gate electrodes 230, the gate electrodes 230 adjacent to the gate electrode 230 forming the string select transistor and the ground select transistor, for example, may be configured as dummy gate electrodes.

The gate electrodes 230 may include a metal material such as tungsten (W), for example. In an example embodiment, the gate electrodes 230 may include polycrystalline silicon or metal a silicide material. In an example embodiment, the gate electrodes 230 may further include a diffusion barrier layer, and the diffusion barrier layer may include, for example, tungsten nitride (WN), tantalum nitride (TaN), titanium nitride (TiN), or a combination thereof.

The interlayer insulating layers 220 may be disposed between the gate electrodes 230. Similarly to the gate electrodes 230, the interlayer insulating layers 220 may be disposed to be spaced apart from each other in the z direction. The interlayer insulating layers 220 may include an insulating material such as silicon oxide or silicon nitride.

In the second memory cell region CELL2, the support layer 203 and the substrate insulating layer 202 may be further disposed on the uppermost interlayer insulating layer 220. The support layer 203 and the substrate insulating layer 202 may be provided to facilitate a manufacturing process. The support layer 203 may be disposed above the gate electrodes 230 and below the second bit lines 270U and the second channel pads 255U such that the support layer 203 may surround the second channel structures CH2. The support layer 203 may include, for example, polycrystalline silicon, and the substrate insulating layer 202 may include an insulating material such as silicon oxide or silicon nitride.

Each of the first and second channel structures CH1 and CH2 may form a single memory cell string. The first and second channel structures CH1 and CH2 may form rows and columns to penetrate the gate electrodes 230 and may be spaced apart from each other. The first and second channel structures CH1 and CH2 may be disposed to form a grid pattern or may be disposed in a zigzag shape in one direction. The first and second channel structures CH1 and CH2 have a column shape and may have inclined side surfaces depending on an aspect ratio. The first and second channel structures CH1 and CH2 may have side surfaces inclined in the same direction. In an example embodiment, both the first and second channel structures CH1 and CH2 may have an inclined side surface of which a width increases toward the substrate 101. In an example embodiment, a portion of the first and second channel structures CH1 and CH2 may be configured as dummy channels.

The channel layers 240 may be disposed in the first and second channel structures CH1 and CH2, and may be configured to be connected to each other between the first and second channel structures CH1 and CH2. Accordingly, each channel layer 240 may extend continuously between the first channel structure CH1 and the second channel structure CH2 adjacent to each other vertically. In an example embodiment, when the channel layer 240 of the first channel structure CH1 is referred to as a first channel layer and the channel layer 240 of the second channel structure CH2 is referred to as a second channel layer, the first channel layer and the second channel layer may be connected to each other in a region surrounded by the source conductive layer 260.

In the first and second channel structures CH1 and CH2, the channel layers 240 may be configured to have an annular shape surrounding the channel filling insulating layer 250, but in an example embodiment, the channel layers 240 may have a columnar shape such as a cylinder or a prism without the channel filling insulating layer 250 inside. The channel layers 240 may include a semiconductor material such as polycrystalline silicon or single crystalline silicon, and the semiconductor material may be an updoped material, but the materials may be varied. In an example embodiment, the semiconductor material may include p-type or n-type impurities. The channel layers 240 may be directly in contact with and connected to the source conductive layer 260 between the first and second channel structures CH1 and CH2. The channel layers 240 may be connected to the first and second channel pads 255L and 255U on ends adjacent to the first and second bit lines 270L and 270U.

The gate dielectric layers 245 may be disposed between the gate electrodes 230 and the channel layers 240, respectively. However, differently from the channel layers 240, the gate dielectric layers 245 may be separated from each other without being connected to each other between the first and second channel structures CH1 and CH2. In an example embodiment, when the gate dielectric layer 245 of the first channel structure CH1 is referred to as a first gate dielectric layer, and the gate dielectric layer 245 of the second channel structure CH2 is referred to as a second gate dielectric layer, the first gate dielectric layer and the second gate dielectric layer may be spaced apart from each other vertically, for example, in the z direction.

As shown in FIG. 5, the gate dielectric layers 245 may include the tunneling layer 241, the charge storage layer 242, and the blocking layer 243, stacked in order from the channel layers 240. The tunneling layer 241 may tunnel an electric charge to the charge storage layer 242, and may include, for example, silicon oxide (SiO₂), silicon nitride (Si₃N₄), silicon oxynitride (SiON), or a combination thereof. The charge storage layer 242 may be configured as a charge trap layer or a floating gate conductive layer. The blocking layer 243 may include silicon oxide (SiO₂), silicon nitride (Si₃N₄), silicon oxynitride (SiON), a high-k dielectric material, or a combination thereof. In an example embodiment, the blocking layer 243 may further include a layer extending in a horizontal direction along the gate electrodes 230. In an example embodiment, the entire blocking layer 243 may be disposed to extend in a horizontal direction along the gate electrodes 230.

The channel filling insulating layers 250 may be disposed to fill an internal side of the channel layers 240. The channel filling insulating layers 250 may be configured to be connected to each other between the first and second channel structures CH1 and CH2. Accordingly, the channel filling insulating layers 250 may extend continuously in a region surrounded by the source conductive layer 260 between the first and second channel structures CH1 and CH2. The channel filling insulating layers 250 may include, for example, silicon oxide (SiO₂), silicon nitride (Si₃N₄), silicon oxynitride (SiON), or a combination thereof.

The first and second channel pads 255L and 255U may be disposed to cover lower and upper surfaces of the channel filling insulating layers 150 and to be electrically connected to the channel layer 240, respectively. The first and second channel pads 255L and 255U may include, for example, doped polycrystalline silicon.

The separation insulating layers 210 may be disposed to penetrate the gate electrodes 230 of the first and second memory cell regions CELL1 and CELL2 and may extend in the x direction. The separation insulating layers 210 may have side surfaces inclined such that a width of each of the separation insulating layers 210 may decrease upwardly, for example, so that an upper width is less than a lower width. Each of the separation insulating layers 210 may include a lower region extending by penetrating the first memory cell regions CELL1 and the source conductive layer 260 and an upper region extending by penetrating the second memory cell region CELL2. The upper region may be partially recessed into the support layer 203. In another implementation, the upper region may completely penetrate the support layer 203. The lower region and the upper region may be connected to each other at a height corresponding to the upper surface of the source conductive layer 260 such that the lower region and the upper region may form a single separation insulating layer 210. Accordingly, the separation insulating layer 210 may have a bent portion of which a width is changed, for example, narrowed, between the lower region and the upper region.

The separation insulating layers 210 may include an insulating material such as silicon oxide and silicon nitride. In an example embodiment, a conductive layer may be further disposed in the separation insulating layers 210. In this case, the conductive layer may function as a contact plug connected to the source conductive layer 260 of the semiconductor device 100 or may be a layer which does not have any electrical function.

The source conductive layer 260 may be disposed to overlap the first and second channel structures CH1 and CH2 in the z direction between the first and second channel structures CH1 and CH2. The source conductive layer 260 may have a plate shape extending in the xy plane between the separation insulating layers 210 disposed adjacent to each other in the y direction. The source conductive layer 260 may apply an electrical signal to the first and second channel structures CH1 and CH2, and may function as the common source line CSL shown in FIG. 3A. The semiconductor device 100 may be integrated with a higher density due to the structure in which the first and second memory cell regions CELL1 and CELL2 share the source conductive layer 260.

At least a portion of external surfaces of the source conductive layer 260 may be in contact with the separation insulating layer 210. As shown in FIG. 5, internal surfaces of the source conductive layer 260 may surround the channel layer 240 and may be directly in contact with the channel layer 240 between the first and second channel structures CH1 and CH2 adjacent to each other vertically. With the source conductive layer 260 surrounding the channel layers 240 and connected to the channel layers 240, the source conductive layer 260 may be stably electrically connected to the first and second channel structures CH1 and CH2. In a region in which the source conductive layer 260 is in contact with the channel layer 240, the gate dielectric layer 245 may be removed from a circumference of the channel layer 240. Accordingly, the source conductive layer 260 may have a plate shape, and may have regions protruding downwardly towards the first channel structures CH1 and regions protruding upwardly towards the second channel structures CH2.

In an example embodiment, an overall width L1 of the upper surface of the source conductive layer 260 facing, for example, overlapping, the second channel structure CH2 in the region protruding upwardly may be greater than an overall width L2 of the lower surface facing the first channel structures CH1 in the region protruding downwardly. The “overall width” refers to a maximum width between both ends of the source conductive layer 260 including the channel filling insulating layer 250 and the channel layer 240 disposed therein.

In an example embodiment, the source conductive layer 260 may have a first thickness T1 in a region spaced apart from the first and second channel structures CH1 and CH2 in the y direction, a second thickness T2 greater than the first thickness T1 on an external side of the channel layer 240, and a third thickness T3 greater than the second thickness T2 in a region in contact with the channel layer 240. The above-described structure may be formed as the gate dielectric layer 245 is removed in a vertically expanded form during the manufacturing process. In the example embodiment, a first length D1 formed as the source conductive layer 260 is expanded while being upwardly recessed into the gate dielectric layer 245 may be the same as or similar to a second length D2 formed as the source conductive layer 260 is expanded while being downwardly recessed into the gate dielectric layer 245.

The source conductive layer 260 may include a semiconductor material or a metal material, such as polycrystalline silicon (Si), tungsten (W), aluminum (Al), copper (Cu), tungsten nitride (WN), and tantalum nitride (TaN), titanium nitride (TiN), or a combination thereof, for example. When the source conductive layer 260 includes polycrystalline silicon, polycrystalline silicon may be a doped layer. In an example embodiment, the source conductive layer 260 may have a multilayer structure.

The first and second horizontal conductive layers 212 and 214 may be disposed on the lower surface and the upper surface of the source conductive layer 260 between the first and second channel structures CH1 and CH2. The first and second horizontal conductive layers 212 and 214 may include the same material, and may include a material different from that of the interlayer insulating layers 220. In an example embodiment, the first and second horizontal conductive layers 212 and 214 may include polycrystalline silicon. In an example embodiment, the first and second horizontal conductive layers 212 and 214 may include a material the same as that of the source conductive layer 260. However, even in this case, the first and second horizontal conductive layers 212 and 214 may be formed in a process different from the process for forming the source conductive layer 260 such that a boundary therebetween may be distinct.

The first and second wiring structures LI and UI may include wirings electrically connecting the first and second memory cell regions CELL1 and CELL2 to the peripheral circuit region PERI, respectively.

The first contact plugs 272 and the second contact plugs 274 may connect the first and second channel pads 255L and 255U to the first and second bit lines 270L and 270U. The third contact plugs 276 may connect the first and second bit lines 270L and 270U to the second bonding pads 280 and upper wiring lines 275, respectively.

The first and second bit lines 270L and 270U may be wiring layers, and may be disposed to be connected to the first and second channel pads 255L and 255U through the first contact plugs 272 and the second contact plugs 274 below and above the first and second channel structures CH1 and CH2, respectively. The first and second bit lines 270L and 270U may extend in the y direction, for example. The upper wiring lines 275 may be disposed to be connected to the second bit lines 270U through the third contact plugs 276 on the second bit lines 270U.

The first contact plugs 272, the second contact plugs 274, the third contact plugs 276, the first and second bit lines 270L and 270U, and the upper wiring lines 275 may include a semiconductor material such as polycrystalline silicon, or a metal material such as tungsten (W), aluminum (Al), copper (Cu), tungsten nitride (WN), tantalum nitride (TaN), titanium nitride (TiN), or a combination thereof.

The second bonding pads 280 may be disposed below the third contact plugs 276 such that a lower surface of the second bonding pads 280 may be exposed to the lower surface of the second semiconductor structure S2 through the cell region insulating layer 290. The second bonding pads 280 may, along with the first bonding pads 180, function as a bonding layer for bonding the first semiconductor structure S1 and the second semiconductor structure S2 together. The second bonding pads 280 may have a total planar size larger than those of the other wiring structures to provide the bonding with the first semiconductor structure S1 and an electrical connection path according to the bonding. The second bonding pads 280 may have a quadrangular shape, a circular shape, or an oval shape on a plane, for example, and may be arranged to form a certain pattern. The second bonding pads 280 may include a conductive material such as copper (Cu), for example.

In an example embodiment, the number of layers and the arrangement of the wiring lines and the contact plugs included in the first and second wiring structures LI and UI may be varied. In an example embodiment, the wiring lines may be further disposed between the second bonding pads 280 and the first bit lines 270L.

The cell region insulating layer 290 may be disposed to cover the gate electrodes 230, and the first and second wiring structures LI and UI may be disposed in the cell region insulating layer 290. The cell region insulating layer 290 may be formed of an insulating material, and may include at least one of silicon oxide, silicon nitride, and silicon carbide, for example. The cell region insulating layer 290 may include a plurality of layers formed in different processes. In an example embodiment, the lower cell region insulating layer 290 may include a bonding dielectric layer having a predetermined thickness on a lower end on which the second bonding pad 280 is disposed. A bonding dielectric layer may also be disposed on the upper surface of the first semiconductor structure S1 such that dielectric-to-dielectric bonding may be achieved. The bonding dielectric layer may also function as a diffusion barrier layer of the second bonding pad 280, and may include at least one of SiO, SiN, SiCN, SiOC, SiON, and SiOCN, for example.

The first and second semiconductor structures S1 and S2 may be bonded to each other by the bonding between the first and second bonding pads 180 and 280, such as copper (Cu) to copper (Cu) bonding, for example. In an example embodiment, the first and second semiconductor structures S1 and S2 may also be bonded to each other by the bonding between the first and second bonding pads 180 and 280, and hybrid bonding by the dielectric to dielectric bonding between the peripheral insulating layer 190 and the second cell region insulating layer 290 disposed on a circumference of the first and second bonding pads 180 and 280.

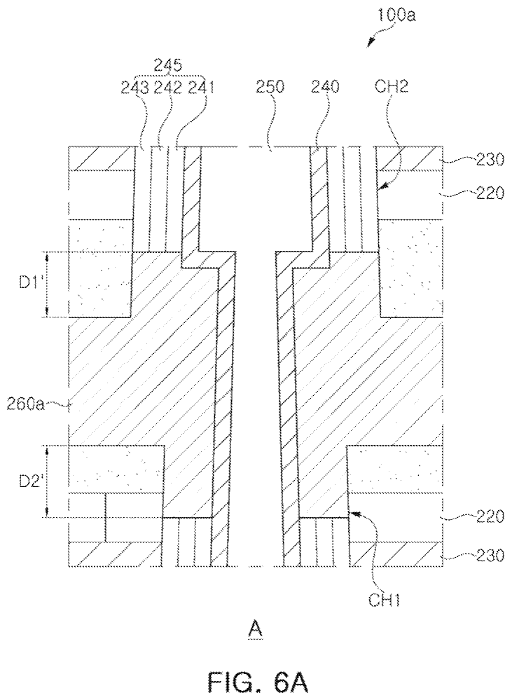

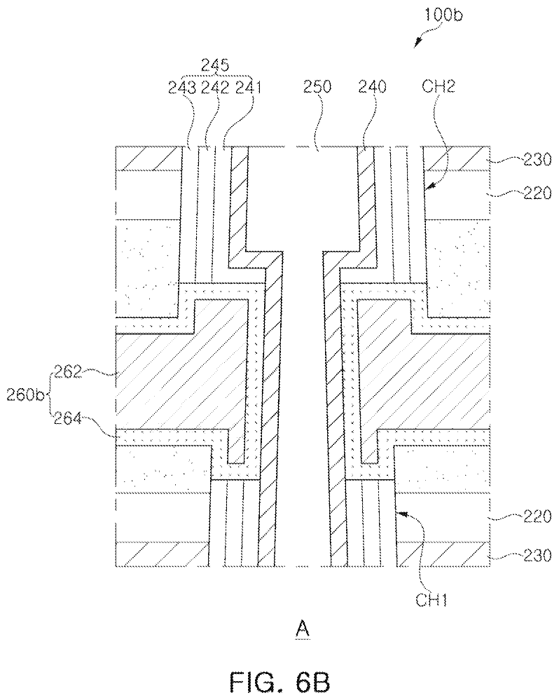

FIGS. 6A and 6B are schematic enlarged cross-sectional views showing a portion of a semiconductor device according to example embodiments, showing a region corresponding to region “A” in FIG. 4 in enlarged form.

Referring to FIG. 6A, in a semiconductor device 100a, a source conductive layer 260a may have a shape that is further expanding upwardly and downwardly as compared to the example embodiment shown in FIG. 5. The source conductive layer 260a may extend by various lengths in a range in which the source conductive layer 260a is not in contact with the gate electrodes 230, such that the source conductive layer 260a may have an elevated upper surface and a lowered lower surface, relative to the previous example embodiment. In the present example embodiment, a first length D1′ (extended as the source conductive layer 260a is expanded while being recessed into the gate dielectric layer 245 upwardly) may be less than a second length D2′ (extended as the source conductive layer 260a is expanded while being recessed into the gate dielectric layer 245 downwardly). However, in an example embodiment, relative sizes of the first length D1′ and the second length D2′ may be varied depending on a thickness of the gate dielectric layer 245, or the like.

Referring to FIG. 6B, in a semiconductor device 100b, a source conductive layer 260b may include an internal conductive layer 262 and a barrier layer 264 extending along an external surface of the internal conductive layer 262. The barrier layer 264 may be in contact with the channel layer 240. In an example embodiment, the internal conductive layer 262 may include tungsten (W), and the barrier layer 264 may include tungsten nitride (WN), tantalum nitride (TaN), titanium nitride (TiN), or a combination thereof.

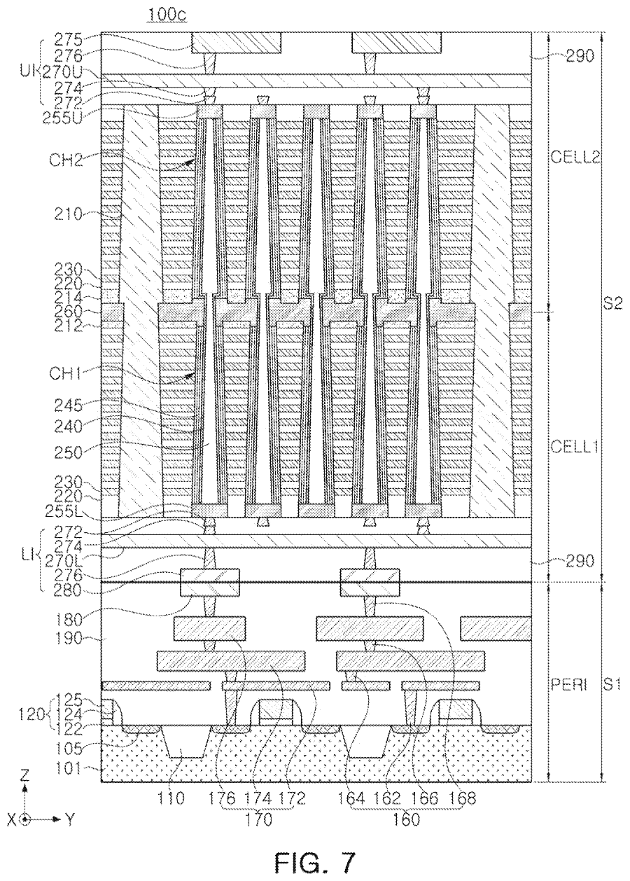

FIG. 7 is a schematic enlarged cross-sectional view showing a semiconductor device according to an example embodiment.

Referring to FIG. 7, differently from the example embodiment in FIG. 4, a semiconductor device 100c may not include a support layer 203 and may not include a substrate insulating layer 202. Accordingly, an uppermost interlayer insulating layer 220 may have a thickness relatively greater than thicknesses of the other lower interlayer insulating layers 220. The second channel pads 255U may be disposed in the uppermost interlayer insulating layer 220. Depending on the thickness of the uppermost interlayer insulating layer 220, the second channel pads 255U may have a thickness smaller than in the example embodiment shown in FIG. 4.

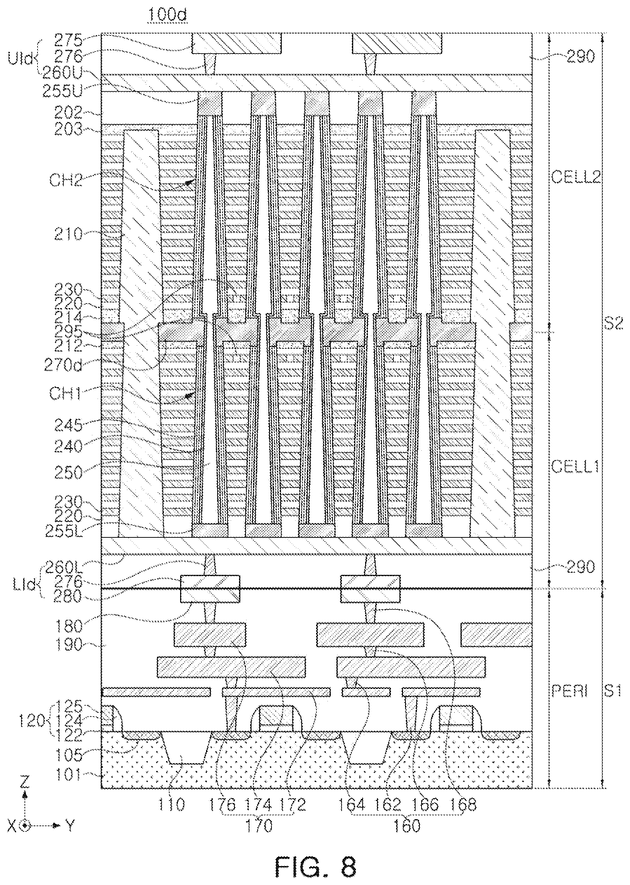

FIG. 8 is a schematic cross-sectional view showing a semiconductor device according to an example embodiment.

Referring to FIG. 8, in a semiconductor device 100d, a second semiconductor structure S2 may include common bit lines 270d which are central wiring layers, and first and second memory cell regions CELL1 and CELL2 stacked vertically around common bit lines 270d. The semiconductor device 100d may further include wiring insulating layers 295, and the first and second wiring structures LId and UId may include first and second source conductive layers 260L and 260U, respectively.

The common bit lines 270d may overlap the first and second channel structures CH1 and CH2 in the z direction between the first and second channel structures CH1 and CH2 and may be disposed along circumferences of the first and second channel structures CH1 and CH2. The common bit lines 270d may be disposed as a single layer between the separation insulating layers 210. The common bit lines 270d may apply an electrical signal to the first and second channel structures CH1 and CH2 and may function as the common bit lines BL0 to BL2 shown in FIG. 3B. By including the structure in which the first and second memory cell regions CELL1 and CELL2 share the common bit lines 270d, the semiconductor device 100d may be integrated with higher density.

External surfaces of the common bit lines 270d may be in contact with the separation insulating layers 210. The internal surfaces of the common bit lines 270d may surround the channel layer 240 between the first and second channel structures CH1 and CH2 vertically adjacent to each other and may be directly in contact with the channel layer 240. With the common bit lines 270d surrounding the channel layers 240 and being connected to the channel layers 240, the common bit lines 270d may be stably electrically connected to the first and second channel structures CH1 and CH2. In a region in which the common bit line 270d is in contact with the channel layer 240, the gate dielectric layer 245 on the circumference of the channel layer 240 may be removed. The common bit lines 270d may have a relatively thick region between the first and second channel structures CH1 and CH2. However, in an example embodiment, thicknesses of the common bit lines 270d may be varied along the y direction.

The wiring insulating layers 295 may be interposed between gate electrodes 230 forming respective string select transistors vertically adjacent to the common bit lines 270d. The wiring insulating layers 295 may isolate the gate electrodes 230 from each other between the first and second channel structures CH1 and CH2 adjacent to each other in the y direction such that the first and second channel structures CH1 and CH2 may be independently controlled. In an example embodiment, the arrangement form and sizes of the wiring insulating layers 295 may be varied. The wiring insulating layer 295 may include an insulating material such as silicon oxide or silicon nitride.

The first and second source conductive layers 260L and 260U may be disposed in a form of plate below and above the first and second channel pads 255L and 255U so as to be connected to the first and second channel pads 255L and 255U, respectively. The first and second source conductive layers 260L and 260U may be connected to the second bonding pads 280 and the upper wiring lines 275 through contact plugs 276, respectively. However, in an example embodiment, the arrangement form of the first and second source conductive layers 260L and 260U and the connection form with the other wiring layers in the first and second wiring structures LId and UId may be varied.

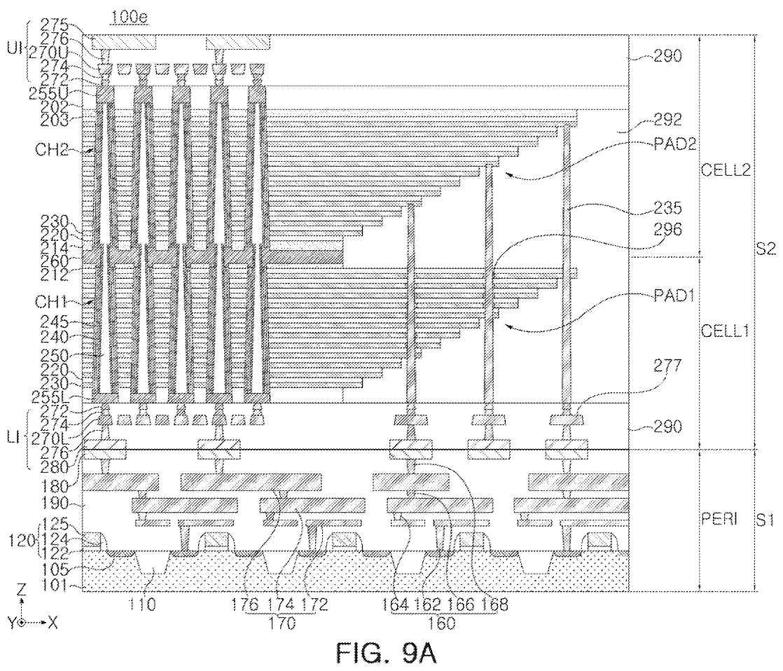

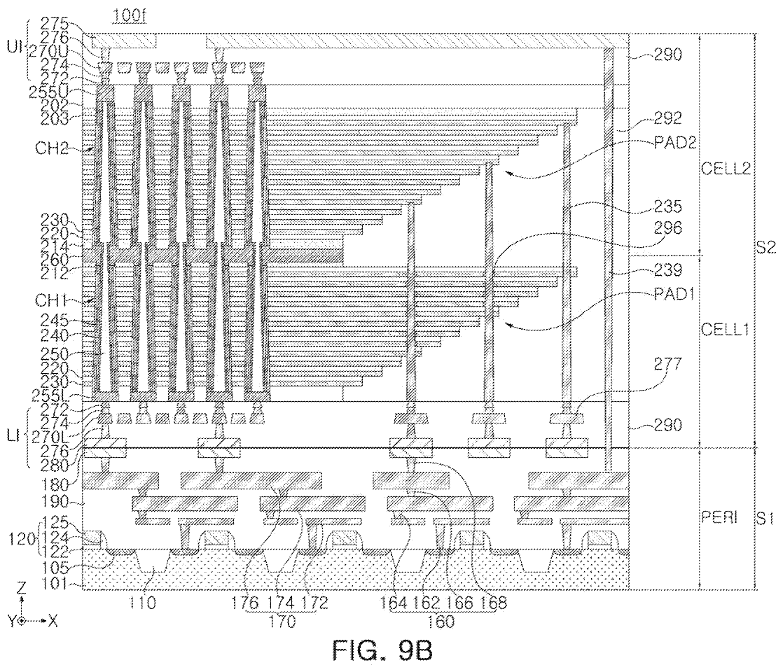

FIGS. 9A and 9B are schematic cross-sectional views showing a semiconductor device according to example embodiments.

FIG. 9A shows first and second pad regions PAD1 and PAD2 of the first and second memory cell regions CELL1 and CELL2 in a semiconductor device 100e. The first and second pad regions PAD1 and PAD2 may be regions in which ends of the gate electrodes 230 in one direction, for example, the x direction, are disposed. The semiconductor device 100e may further include cell contact plugs 235 connected to the gate electrodes 230 in the first and second pad regions PAD1 and PAD2.

In the first and second pad regions PAD1 and PAD2, the gate electrodes 230 may extend by different lengths, in the x direction for example, such that the gate electrodes 230 may form stepped portions in a staircase shape. In the first pad region PAD1 of the first memory cell region CELL1 and the second pad region PAD2 of the second memory cell region CELL2, the gate electrodes 230 may each form the same staircase shape. As shown in FIG. 9A, in the gate electrodes 230 in the first and second pad regions PAD1 and PAD2, two gate electrodes 230 corresponding to each other from an upper portion may extend by substantially the same length. The gate electrodes 230 of the first and second pad regions PAD1 and PAD2 may be covered by a pad insulating layer 292.

In an example embodiment, a certain number of the gate electrodes 230, two to six gate electrodes 230, for example, may form a single gate group and may form stepped portions between the gate groups in the x direction. In this case, the gate electrodes 230 forming the single gate group may be disposed to have stepped portions in the y direction as well. By including the stepped portions, the gate electrodes 230 may form a staircase shape in which the lower gate electrode 230 extends further than the upper gate electrode 230 such that ends exposed upwardly from the interlayer insulating layers 220 may be provided. In an example embodiment, the gate electrodes 230 may have an increased thickness on the ends.

The cell contact plugs 235 may be disposed to penetrate both the first and second pad regions PAD1 and PAD2. The cell contact plugs 235 may be electrically connected to a single gate electrode 230 of the first pad region PAD1 and a single gate electrode 230 of the second pad region PAD2. The cell contact plugs 235 may be separated from the gate electrodes 230 which are not electrically connected thereto by contact insulating layers 296. In the semiconductor device 100e, the first and second channel structures CH1 and CH2 may form different memory cell strings and may be independently driven by the first and second bit lines 270L and 270U. Accordingly, the cell contact plugs 235 may be arranged to be simultaneously electrically connected to the two gate electrodes 230, which are disposed in the first and second memory cell regions CELL1 and CELL2, respectively.

The cell contact plugs 235 may have an inclined side surface such that a width thereof increases toward the substrate 101, the shape may be varied. The cell contact plugs 235 may be connected to the lower wiring lines 277 through the first and second contact plugs 272 and 274 in a lower portion. The cell contact plugs 235 and the lower wiring lines 277 may include a conductive material tungsten (W), copper (Cu), aluminum (Al), or the like, for example.

The contact insulating layers 296 may be disposed to surround the cell contact plugs 235 on the same level as the level of the gate electrodes 230. However, in an example embodiment, the arrangement form and the shape of the contact insulating layers 296 may be varied.

Referring to FIG. 9B, differently from the embodiment of FIG. 9A, a semiconductor device 100f may further include a through contact plug 239.

The through contact plug 239 may directly connect a wiring layer of the first semiconductor structure S1 to a wiring layer of the second semiconductor structure S2. In an example embodiment, the through contact plug 239 may connect the upper wiring line 275 of the second wiring structure UI to the third circuit wiring line 176 of the peripheral circuit region PERI. In this case, the through contact plug 239 may have an inclined side surface such that a width thereof decreases toward the substrate 101. Accordingly, a side surface of the through contact plug 239 may have an inclination formed in a direction opposite to the cell contact plugs 235. In an example embodiment, the through contact plug 239 may include a plurality of contact plugs connected to each other vertically and continuously, e.g., in a stack.

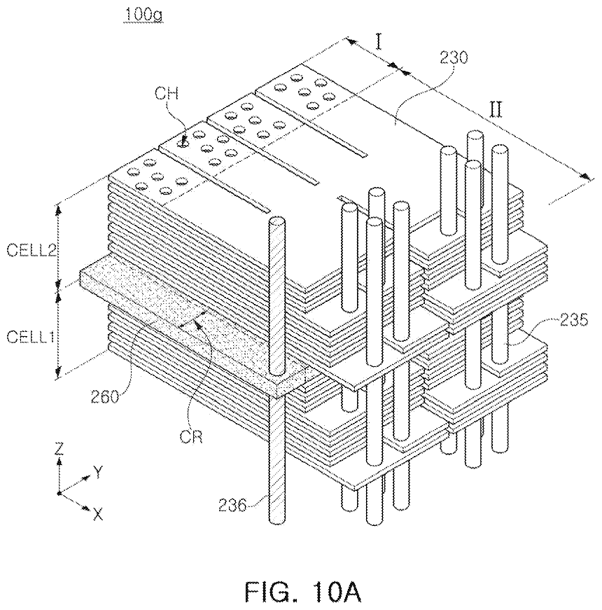

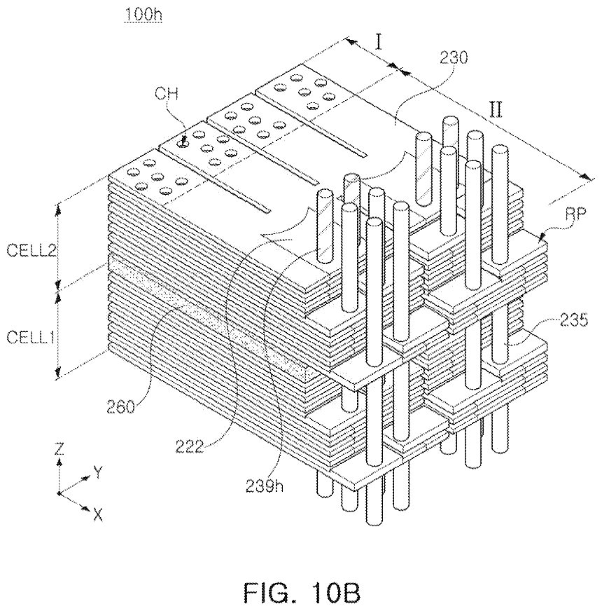

FIGS. 10A and 10B are schematic perspective views showing a semiconductor device according to an example embodiment.

FIGS. 10A and 10B show a portion of gate electrodes 230, a source conductive layer 260, cell contact plugs 235, and a source contact plug 236, in a first region I in which channel structures CH of a semiconductor device are disposed and a second region II which is a pad region. Memory cell strings are disposed in the first region I, and the second region II may correspond to the first and second pad regions PAD1 and PAD2 shown in FIGS. 9A and 9B.

Referring to FIG. 10A, the source conductive layer 260 of the semiconductor device 100g may have a contact region CR protruding in the y direction from side surfaces of the gate electrodes 230 on ends of the gate electrodes 230 taken in the y direction. The contact region CR may be a region in which the separation insulating layers 210 (see FIG. 4) are disposed. In another implementation, the contact region CR may be configured as an external region of an outermost end of the gate electrodes 230 forming memory cell arrays MCA1 and MCA2 (see FIG. 2) which share a single common source line CSL (see FIG. 3A).

The source contact plug 236 may be connected to the source conductive layer 260 in the contact region CR. The source contact plug 236 may electrically connect the first wiring structure LI and/or the second wiring structure UI shown in FIG. 4 to the source conductive layer 260, and may electrically connect the peripheral circuit region PERI to the source conductive layer 260. In an example embodiment, the source contact plug 236 may not penetrate and extend the source conductive layer 260, but may only extend to a region above or below the source conductive layer 260.

Referring to FIG. 10B, in a semiconductor device 100h, gate electrodes 230 may be disposed to surround sacrificial gate layers 222 in the second region II. Also, the semiconductor device 100h may include a through contact plug 239h extending through the sacrificial gate layers 222.

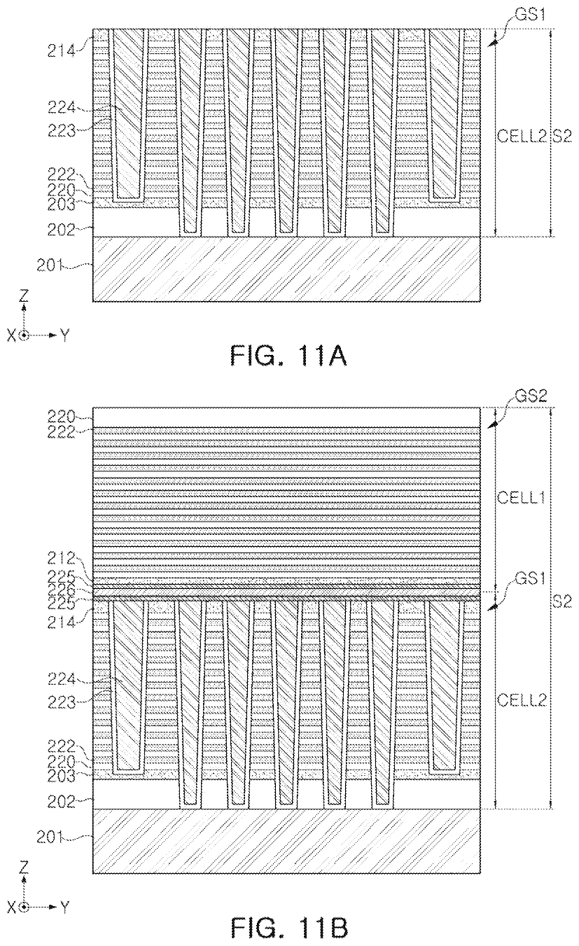

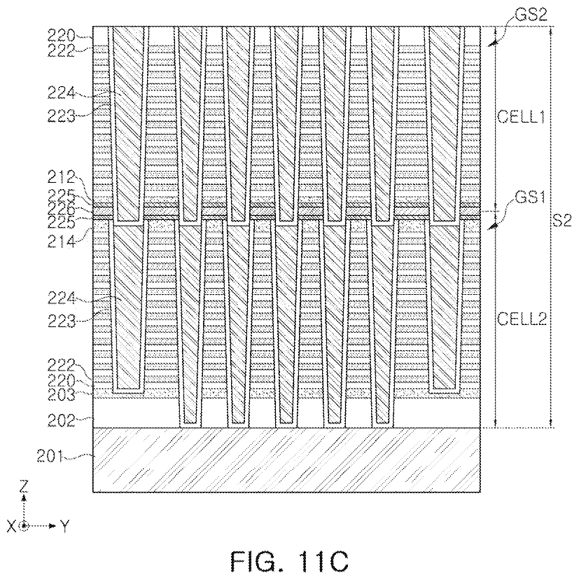

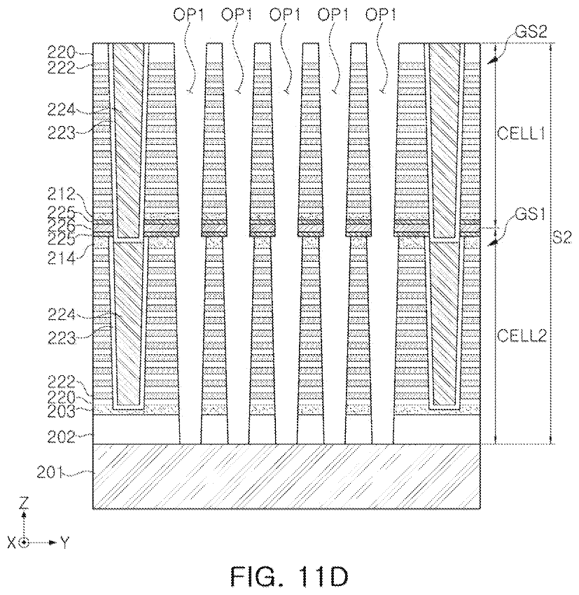

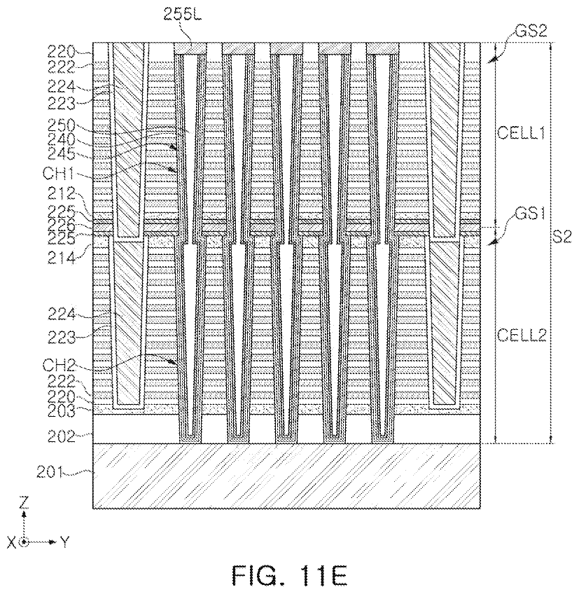

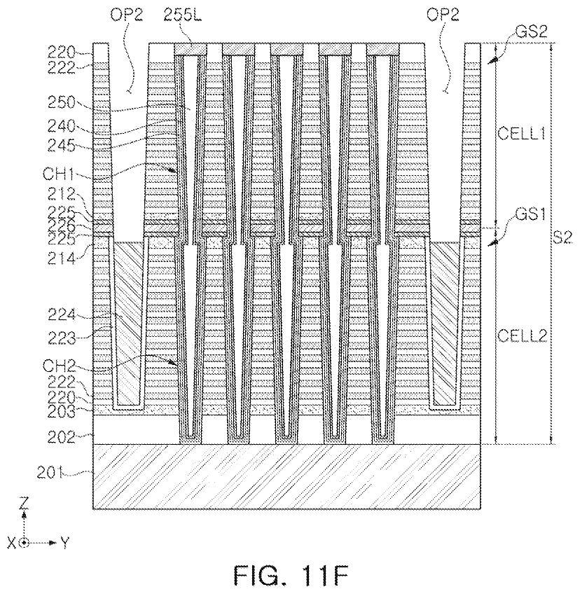

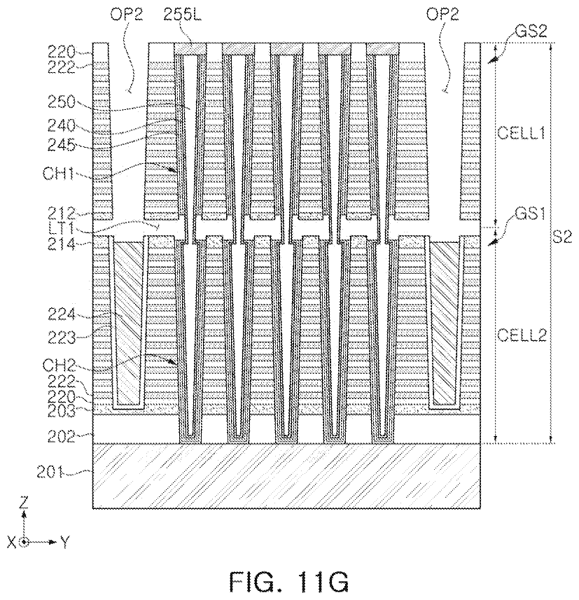

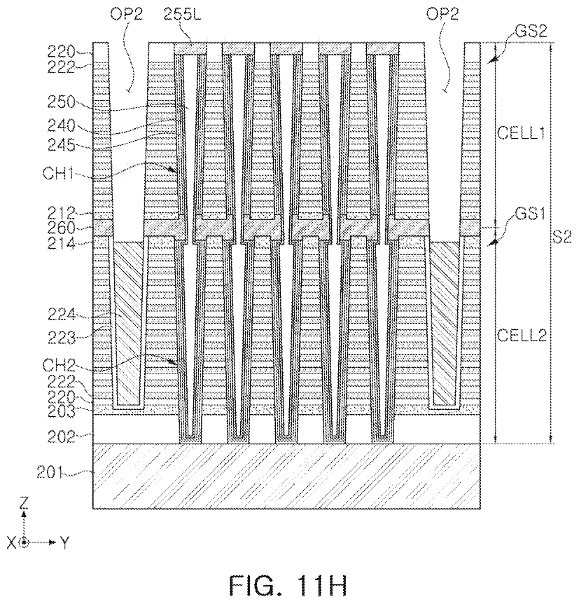

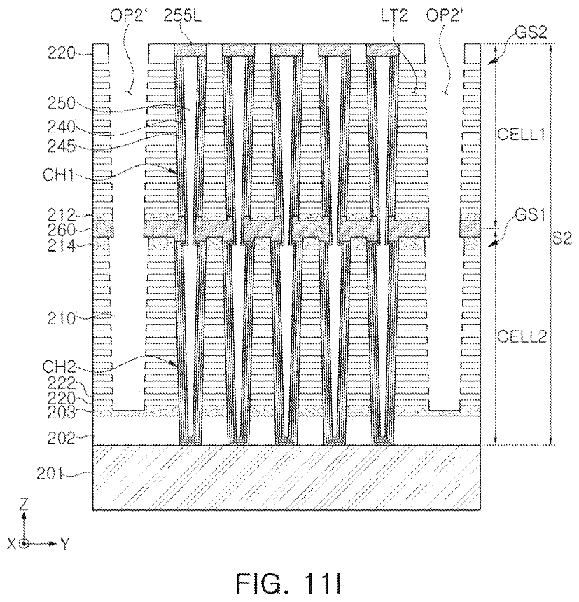

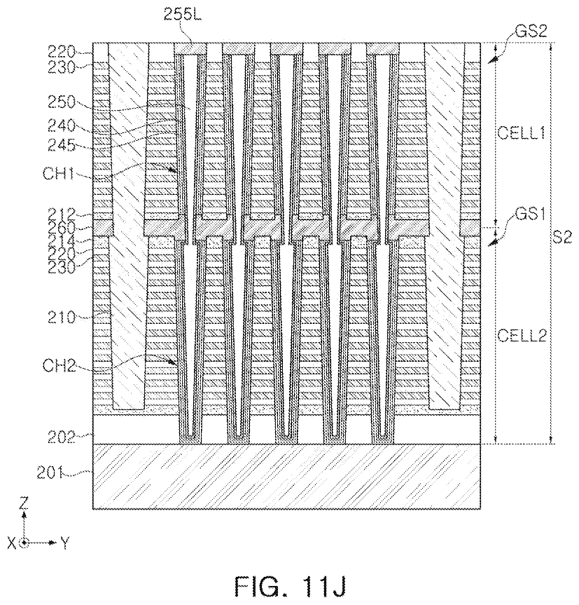

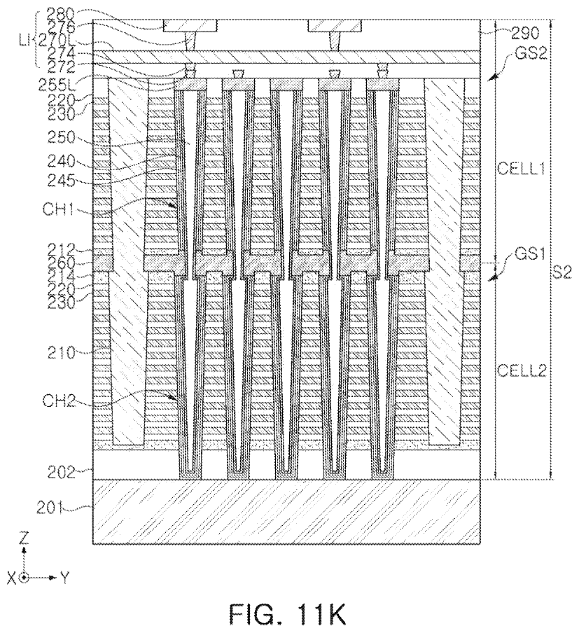

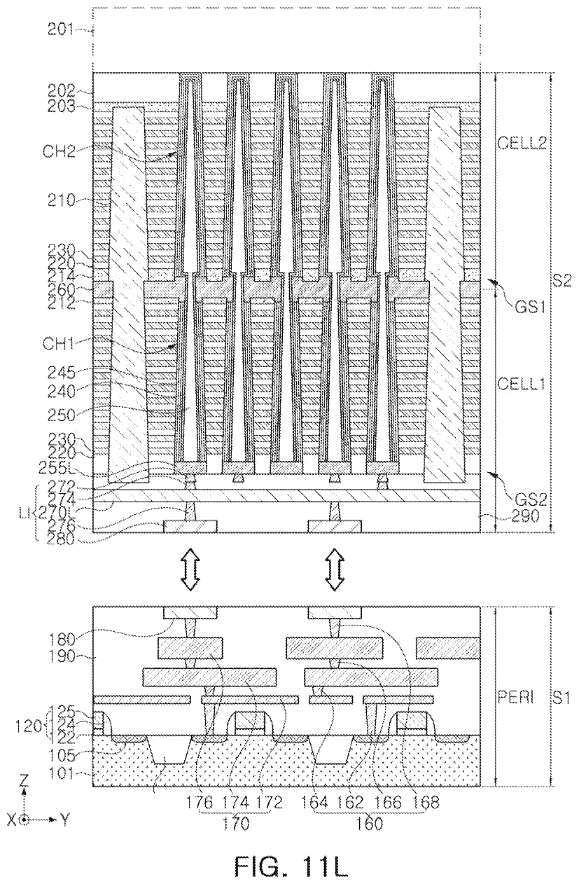

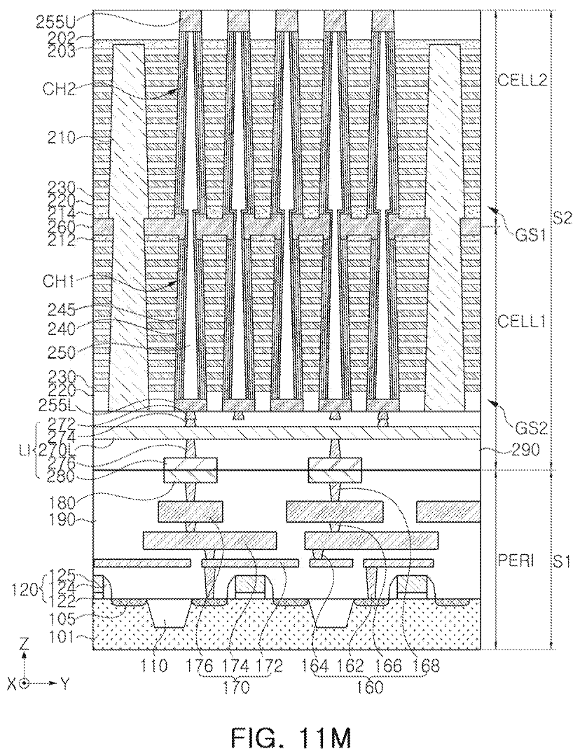

A portion of the sacrificial gate layers 222 may not be removed and may remain in a process described with reference to FIG. 11I. In the example embodiment, a region in which the sacrificial gate layers 222 remain may be used as a through wiring region.

The cell contact plugs 235 may penetrate the sacrificial gate layers 222 and may be connected to a total of two gate electrodes 230, one in each of the first and second memory cell regions CELL1 and CELL2. The cell contact plugs 235 may be connected to upwardly exposed gate electrodes 230 of the gate electrodes 230 forming a staircase shape. The gate electrodes 230 may have an increased thickness in a connection region RP, which is a region connected to the cell contact plugs 235.

The through contact plugs 239h may penetrate the sacrificial gate layers 222 and may extend to connect the first wiring structure LI to the second wiring structure UI in the second semiconductor structure S2. In another implementation, the through contact plug 239h may also extend to directly connect the second wiring structure UI of the second semiconductor structure S2 to the circuit wiring line 170 of the first semiconductor structure S1, as shown in FIG. 9B.

FIGS. 11A to 11M are schematic cross-sectional views showing a method of manufacturing a semiconductor device according to an example embodiment, showing a region corresponding to FIG. 4.

Referring to FIG. 11A, firstly, a second semiconductor structure S2 may be manufactured. To this end, a substrate insulating layer 202 and a support layer 203 may be formed, in order, on a base substrate 201, interlayer insulating layers 220 and sacrificial gate layers 222 may be alternately stacked, and a second horizontal conductive layer 214 may be formed, thereby forming a lower stack structure GS1. Thereafter, the lower stack structure GS1 may be partially removed, and first and second through-sacrificial layers 223 and 224 may be formed.

The base substrate 201 may be a semiconductor substrate such as silicon (Si), and may be removed through a subsequent process. The substrate insulating layer 202 and the support layer 203 may be formed in order on the base substrate 201 and may include different materials.

The sacrificial gate layers 222 may be replaced with gate electrodes 230 through a subsequent process. The sacrificial gate layers 222 may be formed of a material etched with etch selectivity with respect to the interlayer insulating layers 220. In an example embodiment, the interlayer insulating layer 220 may be formed of at least one of silicon oxide and silicon nitride, and the sacrificial gate layers 222 may be formed of a material different from the material of the interlayer insulating layer 220 selected from among silicon, silicon oxide, silicon carbide, and silicon nitride. In an example embodiment, the interlayer insulating layers 220 may not have the same thickness.

The first and second through-sacrificial layers 223 and 224 may be configured to penetrate the lower stack structure GS1 in positions corresponding to the second channel structures CH2 and upper regions of the separation insulating layers 210 shown in FIG. 4. Firstly, through-holes corresponding to the second channel structures CH2 and through-trenches corresponding to the upper regions of the separation insulating layers 210 may be formed. Due to a height of the lower stack structure GS1, sidewalls of the through-holes and the through-trenches may not be perpendicular to an upper surface of the base substrate 201. The through-trenches may be formed such that a lower end is disposed in the support layer 203, and the through-holes may be configured to extend to the base substrate 201. In an example embodiment, the through-holes may be configured to be partially recessed into the base substrate 201.

The first through-sacrificial layers 223 may be formed to have a uniform thickness along internal side walls and bottom surfaces of the through-holes and the through-trenches, and the second through-sacrificial layers 224 may be formed to fill the through-holes and the through-trenches. The first and second through-sacrificial layers 223 and 224 may include different materials. In an example embodiment, the first through-sacrificial layers 223 may include silicon oxide or silicon nitride, and the second through-sacrificial layers 224 may include polycrystalline silicon.

Referring to FIG. 11B, first and second source sacrificial layers 225 and 226 may be formed on the first stack structure GS1, a first horizontal conductive layer 212 may be formed, interlayer insulating layers 220 and the sacrificial gate layers 222 may be alternately stacked, thereby forming the second stack structure GS2.

The first and second source sacrificial layers 225 and 226 may be stacked on the first stack structure GS1 such that the first source sacrificial layers 225 may be disposed above and below the second source sacrificial layer 226. The first and second source sacrificial layers 225 and 226 may include different materials. The first and second source sacrificial layers 225 and 226 may be replaced with the source conductive layer 260 shown in FIG. 4 through a subsequent process. In an example embodiment, the first source sacrificial layers 225 may be formed of the same material as that of the interlayer insulating layers 220, and the second source sacrificial layer 226 may be formed of the same material as that of the sacrificial gate layers 222 or the support layer 203. The first horizontal conductive layer 212 may be formed on the first and second source sacrificial layers 225 and 226.

The interlayer insulating layers 220 and the sacrificial gate layers 222 may be alternately stacked on the first horizontal conductive layer 212, similarly to the first stack structure GS1.

Referring to FIG. 11C, the upper stack structure GS2 may be partially removed, and the first and second through-sacrificial layers 223 and 224 may be formed.

The first and second through-sacrificial layers 223 and 224 may be formed to penetrate the upper stack structure GS2 in a position corresponding to the first channel structures CH1 and lower regions of the separation insulating layers 210 shown in FIG. 4, similarly to the lower stack structure GS1. Firstly, through-holes corresponding to the first channel structures CH1 and through-trenches corresponding to the lower regions of the separation insulating layers 210 may be formed. The through-holes and the through-trenches may extend to be in contact with the second through-sacrificial layers 224 of the lower stack structure GS1 or to be partially recessed into the second through-sacrificial layers 224.

Referring to FIG. 11D, first openings OP1 may be formed by removing the first and second through-sacrificial layers 223 and 224 formed in positions corresponding to the first and second channel structures CH1 and CH2.

For example, a mask layer may be formed on the upper stack structure GS2 to partially expose the upper stack structure GS2, and the first and second through-sacrificial layers 223 and 224 may be removed in the exposed region. The first and second through-sacrificial layers 223 and 224 may be removed by wet etching, for example. Each of the first openings OP1 may have a hole shape corresponding to the first and second channel structures CH1 and CH2 shown in FIG. 4.

Referring to FIG. 11E, the gate dielectric layer 245, the channel layer 240, and the channel filling insulating layer 250 of the first and second channel structures CH1 and CH2 may be formed in the first openings OP1, and first channel pads 255L may be formed on the first channel structures CH1.

The gate dielectric layer 245 may be formed to have a uniform thickness through atomic layer deposition (ALD) or chemical vapor deposition (CVD). In this process, at least a portion of the gate dielectric layer 245 extending vertically along the channel layer 240 may be formed. The channel layer 240 may be formed on the gate dielectric layer 245. The channel filling insulating layer 250 may be formed to fill the first and second channel structures CH1 and CH2, and may be an insulating material. However, in an example embodiment, a space between the channel layers 240 may be filled with a conductive material, rather than the channel filling insulating layer 250. As described above, in this process, the gate dielectric layer 245, the channel layer 240, and the channel filling insulating layer 250 forming the first and second channel structures CH1 and CH2 may be formed together in a single process.

Thereafter, the first channel pads 255L may be formed on the first channel structures CH1.

Referring to FIG. 11F, in the upper stack structure GS2, second openings OP2 may be formed by removing first and second through-sacrificial layers 223 and 224 formed in positions corresponding to the separation insulating layers 210.

The first and second through-sacrificial layers 223 and 224 may be selectively removed by wet etching, for example. According to example embodiments, the interlayer insulating layers 220 or the sacrificial gate layers 222 exposed through the second openings OP2 may also be removed from the second openings OP2 by a certain thickness such that dimples may be formed.

Referring to FIG. 11G, the first and second source sacrificial layers 225 and 226 may be removed through the second openings OP2 such that a first tunnel portion LT1 may be formed.

Sacrificial spacer layers may be formed in the second openings OP2, the second source sacrificial layer 226 may be selectively removed, and the upper and lower first source sacrificial layers 225 may be removed in order. The first and second source sacrificial layers 225 and 226 may be removed by a wet etching process, for example. During the process of removing the first source sacrificial layers 225, the gate dielectric layer 245 (exposed in the region from which the second source sacrificial layer 226 is removed) may also be partially removed. Accordingly, the channel layers 240 may be exposed through the first tunnel portion LT1.

In this process, by adjusting a degree of partially removing the gate dielectric layer 245, the semiconductor device 100a shown in FIG. 6A may be manufactured.

Referring to FIG. 11H, a source conductive layer 260 may be formed in the first tunnel portion LT1.

The source conductive layer 260 may be formed by depositing a conductive material in the first tunnel portion LT1. The source conductive layer 260 may be formed to be in contact with the exposed channel layers 240 and to surround the channel layers 240. The source conductive layer 260 may be, for example, doped polycrystalline silicon. The source conductive layer 260 may be removed on the second through-sacrificial layers 224 of the lower stack structure GS1, and the sacrificial spacer layers may be removed in this process.

In this process, by preferentially forming the barrier layer 264 and forming the internal conductive layer 262 thereafter, the semiconductor device 100b shown in FIG. 6B may be manufactured.

Referring to FIG. 11I, in the lower stack structure GS1, expanded second openings OP2′ may be formed by removing the first and second through-sacrificial layers 223 and 224 formed in positions corresponding to the separation insulating layers 210, and second tunnel portions LT2 may be formed by removing the sacrificial gate layers 222 through the expanded second openings OP2′.

Firstly, the first and second through-sacrificial layers 223 and 224 may be selectively removed by wet etching, for example.

The expanded second openings OP2′ may have a trench shape extending in the x direction. The sacrificial gate layers 222 may be selectively removed with respect to the interlayer insulating layers 220 using wet etching, for example. Accordingly, sidewalls of the first and second channel structures CH1 and CH2 may be partially exposed through the second tunnel portions LT2 between the interlayer insulating layers 220.

Referring to FIG. 11J, the gate electrodes 230 may be formed in the second tunnel portions LT2, and the separation insulating layers 210 may be formed in the expanded second openings OP2′.

The gate electrodes 230 may be formed by filling a region from which the sacrificial gate layers 222 are removed with a conductive material. The gate electrodes 230 may include metal, polycrystalline silicon, or metal silicide material. In an example embodiment, in the case in which the gate dielectric layer 245 has a region which extends horizontally along the gate electrodes 230, the region may be preferentially formed before forming the gate electrodes 230.

Thereafter, the separation insulating layers 210 may be formed by filling the expanded second openings OP2′ with an insulating material.

Referring to FIG. 11K, a first wiring structure LI may be formed on the upper stack structure GS2.

A cell region insulating layer 290 may be formed, and first contact plugs 272, second contact plugs 274, and first bit lines 270L, third contact plugs 276, and second bonding pads 280, which penetrate the cell region insulating layer 290, may be formed in order. The first contact plugs 272, the second contact plugs 274, and the third contact plugs 276 may be formed by partially forming the cell region insulating layer 290, partially etching the cell region insulating layer 290, and filling the etched region with a conductive material. The first bit lines 270L and the second bonding pads 280 may be formed by depositing a conductive material and patterning the conductive material, for example. Upper surfaces of the second bonding pads 280 may be exposed through the cell region insulating layer 290. According to example embodiments, the upper surfaces of the second bonding pads 280 may be formed to protrude upwardly than the upper surfaces of the cell region insulating layer 290.

In an example embodiment, at least a portion of the elements of the first wiring structure LI may have inclined side surfaces, and in this case, the inclined side surfaces may be inclined in the same direction as the first and second channel structures CH1 and CH2.

Referring to FIG. 11L, the second semiconductor structure S2 may be bonded to the first semiconductor structure S1, and the base substrate 201 may be removed.

Firstly, the first semiconductor structure S1 may be prepared by forming circuit devices 120 and circuit wiring structures on the substrate 101.

Device isolation layers 110 may be formed in the substrate 101, and the circuit gate dielectric layers 122 and the circuit gate electrodes 125 may be formed in order on the substrate 101. The device isolation layers 110 may be formed by a shallow trench isolation (STI) process, for example. The circuit gate dielectric layers 122 and the circuit gate electrodes 125 may be formed using ALD or CVD. The circuit gate dielectric layers 122 may be formed of silicon oxide, and the circuit gate electrodes 125 may be formed of at least one of polysilicon or metal silicide layers, but the materials may be varied. Thereafter, spacer layer 124s and source/drain regions 105 may be formed on both sides of the circuit gate dielectric layer 122 and the circuit gate electrode 125. In an example embodiment, the spacer layers 124 may include a plurality of layers. Thereafter, the source/drain regions 105 may be formed by performing an ion implantation process.

Among the circuit wiring structures, the circuit contact plugs 160 may be formed by partially forming the peripheral insulating layer 190, partially removing the peripheral insulating layer 190 by etching, and filling the etched region with a conductive material. The circuit wiring lines 170 may be formed by depositing a conductive material, for example, and patterning the conductive material. First bonding pads 180 may be formed on the circuit wiring lines 170.

The peripheral insulating layer 190 may include a plurality of insulating layers. The peripheral insulating layer 190 may be partially formed in the processes for forming the circuit wiring structures, and may be partially formed above the third circuit wiring line 176 such that the peripheral insulating layer 190 may be formed to cover the circuit devices 120 and the circuit wiring structures.

Thereafter, the first semiconductor structure S1 and the second semiconductor structure S2 may be connected to each other by bonding the first bonding pads 180 to the second bonding pads 280 by pressing. The second semiconductor structure S2 may be bonded onto the first semiconductor structure S1 upside down such that the second bonding pads 280 may face downwardly. The first semiconductor structure S1 and the second semiconductor structure S2 may be directly bonded to each other without an adhesive such as an adhesive layer interposed therebetween. In an example embodiment, the first bonding pads 180 and the second bonding pads 280 may be bonded to each other at an atomic level by the pressing process. In an example embodiment, to strengthen bonding strength, a surface treatment process such as a hydrogen plasma treatment may be further performed on the upper surface of the first semiconductor structure S1 and the lower surface of the second semiconductor structure S2 before bonding.

In an example embodiment, when the cell region insulating layer 290 includes the above-described bonding dielectric layer thereon, and the first semiconductor structure S1 also has the same layer, bonding strength may be further secured by the bonding between the first and second bonding pads 180 and 280 and also the dielectric bonding between the bonding dielectric layers, for example, hybrid bonding.

Thereafter, on the bonding structure of the first and second semiconductor structures S1 and S2, the base substrate 201 of the second semiconductor structure S2 may be removed.

By removing the base substrate 201, a thickness of the semiconductor device may be reduced, and formation of a structure for wiring, such as a through via, may be omitted. A portion of the base substrate 201 may be removed from the upper surface by a grinding process, and another portion, for example, a remaining portion, of the base substrate 201 may be removed by an etching process such as wet etching.

In this process, by removing the base substrate 201 and also removing the support layer 203, the semiconductor device 100c shown in FIG. 7 may be manufactured.

Referring to FIG. 11M, the gate dielectric layer 245, the channel layer 240, and the channel filling insulating layer 250 may be partially removed from the second channel structures CH2, and the second channel pads 255U may be formed.

The gate dielectric layer 245, the channel layer 240, and the channel filling insulating layer 250 may be removed to a certain depth from an upper portion in a region surrounded by the substrate insulating layer 202. The second channel pads 255U may be formed by depositing a conductive material in a region from which the gate dielectric layer 245, the channel layer 240, and the channel filling insulating layer 250 are removed.

Thereafter, referring back to FIG. 4, a second wiring structure UI may be formed on the second channel structures CH2.

The second wiring structure UI may be formed by the same method as the method for forming the first wiring structure LI described above with reference to FIG. 11K. In an example embodiment, at least a portion of the elements of the second wiring structure UI may have inclined side surfaces, and in this case, the inclined side surfaces may be inclined in a direction opposite to the first and second channel structures CH1 and CH2.

According to the aforementioned example embodiments, in a structure in which two memory cell structures share a central wiring layer, by arranging the central wiring layer to surround the channel layers connected to each other between the memory cell structures, a semiconductor device having improved integration density and reliability may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a first bit line;
a second bit line on the first bit line;
a source conductive layer between the first bit line and the second bit line;
a plurality of first gate electrodes between the first bit line and the source conductive layer, stacked in a first direction perpendicular to an upper surface of the first bit line and spaced apart from each other;
a first channel structure penetrating the plurality of first gate electrodes and including a first channel semiconductor layer electrically connected to the first bit line;
a plurality of second gate electrodes between the source conductive layer and the second bit line, stacked in the first direction and spaced apart from each other; and
a second channel structure penetrating the plurality of second gate electrodes and including a second channel semiconductor layer electrically connected to the second bit line,
wherein the plurality of first gate electrodes are in a height level lower than a height level of a lower surface of the source conductive layer, and the plurality of second gate electrodes are in a height level higher than a height level of an upper surface of the source conductive layer,
wherein the first channel semiconductor layer and the second channel semiconductor layer are connected in a connection region between the first channel structure and the second channel structure, and
wherein the source conductive layer directly contacts the first channel semiconductor layer and the second channel semiconductor layer in the connection region.

2. The semiconductor device as claimed in claim 1, wherein the source conductive layer is configured to apply an electrical signal to the first channel semiconductor layer and the second channel semiconductor layer as a common source line.

3. The semiconductor device as claimed in claim 2,
wherein the source conductive layer has a contact region protruding from side surfaces of the plurality of first gate electrodes and the plurality of second gate electrodes to an external side, and
wherein the semiconductor device further includes a source contact plug connected to the source conductive layer in the contact region and configured to apply the electrical signal.

4. The semiconductor device as claimed in claim 2, wherein the first bit line is configured to apply a first electrical signal to the first channel semiconductor layer, and the second bit line is configured to apply a second electrical signal to the second channel semiconductor layer, independently of the first bit line.

5. The semiconductor device as claimed in claim 1, wherein the source conductive layer spaced apart in the first direction from a lowermost first gate electrode among the plurality of first gate electrodes and an uppermost second gate electrode among the plurality of second gate electrodes.

6. The semiconductor device as claimed in claim 1, wherein each of the first channel structure and the second channel structure has an inclined side surface such that each of the first channel structure and the second channel structure has an increased width towards the first bit line.

7. The semiconductor device as claimed in claim 6, wherein an upper surface of the first channel structure has a width smaller than a width of a lower surface of the second channel structure.

8. The semiconductor device as claimed in claim 1, wherein the source conductive layer expands towards the first channel structure and the second channel structure in the connection region such that the source conductive layer has an increased thickness in the first direction.

9. The semiconductor device as claimed in claim 1, wherein a maximum width of a lower surface of the source conductive layer facing the first channel structure is less than a maximum width of an upper surface of the source conductive layer facing the second channel structure.

10. The semiconductor device as claimed in claim 1,
wherein the first channel structure further includes a first gate dielectric layer between the first channel semiconductor layer and the plurality of first gate electrodes, and the second channel structure further includes a second gate dielectric layer between the second channel semiconductor layer and the plurality of second gate electrodes, and
wherein the first gate dielectric layer and the second gate dielectric layer are spaced apart from each other in the first direction between the first channel structure and the second channel structure.

11. The semiconductor device as claimed in claim 10,
wherein the source conductive layer has protruding regions expanding along the first direction towards the first channel structure and the second channel structure in the connection region, and
wherein the protruding regions directly contact the first gate dielectric layer and the second gate dielectric layer.

12. The semiconductor device as claimed in claim 1, further comprising a first horizontal conductive layer and a second horizontal conductive layer on the upper surface and the lower surface of the source conductive layer, respectively.

13. A semiconductor device, comprising:
a first semiconductor structure including a substrate and a circuit device disposed on the substrate; and
a second semiconductor structure connected to the first semiconductor structure on the first semiconductor structure,
wherein the second semiconductor structure includes:
a plurality of first gate electrodes stacked in a first direction perpendicular to an upper surface of the substrate and spaced apart from each other;
a first channel structure penetrating the plurality of first gate electrodes and including a first channel semiconductor layer;
a first bit line below the first channel structure;
a plurality of second gate electrodes on the first gate electrodes and stacked in the first direction and spaced apart from each other;
a second channel structure penetrating the plurality of second gate electrodes and including a second channel semiconductor layer;
a second bit line on the second channel structure; and
a source conductive layer between an uppermost first gate electrode among the plurality of first gate electrodes and a lowermost second gate electrode among the plurality of second gate electrodes,
wherein the first channel semiconductor layer extends above the first channel structure and the second channel semiconductor layer extends below the second channel structure such that the first channel semiconductor layer and the second channel semiconductor layer are connected in a connection region between the first channel structure and the second channel structure,
wherein the source conductive layer directly contacts the first channel semiconductor layer and the second channel semiconductor layer in the connection region, and
wherein a maximum width of a lower surface of the source conductive layer facing the first channel structure is less than a maximum width of an upper surface of the source conductive layer facing the second channel structure.

14. The semiconductor device as claimed in claim 13, wherein the source conductive layer includes an internal conductive layer and a barrier layer extending along an external surface of the internal conductive layer.

15. The semiconductor device as claimed in claim 14, wherein the barrier layer directly contacts the first channel semiconductor layer and the second channel semiconductor layer in the connection region.

16. The semiconductor device as claimed in claim 13, further comprising:
separation insulating layers penetrating the plurality of first gate electrodes and the plurality of second gate electrodes, extending in a second direction perpendicular to the first direction, and spaced apart from each other in a third direction perpendicular to the first direction and the second direction,
wherein the source conductive layer is a single layer between the separation insulating layers adjacent to each other in the third direction.

17. The semiconductor device as claimed in claim 13, wherein the source conductive layer has a first region having a first thickness in the first direction, and has a second region having a second thickness in the first direction that is greater than the first thickness.

18. The semiconductor device as claimed in claim 17, wherein the second region is surrounded by the first region.

19. The semiconductor device as claimed in claim 13,
wherein the first channel structure and the second channel structure form a first memory cell string and a second memory cell string, respectively, and
wherein the first memory cell string and the second memory cell string are independently controlled by the first bit line and the second bit line, respectively.

20. The semiconductor device as claimed in claim 13,
wherein the source conductive layer is configured to apply an electrical signal to the first channel semiconductor layer and the second channel semiconductor layer as a common source line, and
wherein the first bit line is configured to apply a first electrical signal to the first channel semiconductor layer, and the second bit line is configured to apply a second electrical signal to the second channel semiconductor layer.
